(19) United States
(12) Patent Application Publication
(10) Pub. No.: US 2013/0265700 A1
(43) Pub. Date: Oct. 10, 2013

(54) DALI CONTROLLER

(71) Applicants: Andrew Parker, Macquarie Park (AU); Michael Randall, Macquarie Park (AU)

(72) Inventors: Andrew Parker, Macquarie Park (AU); Michael Randall, Macquarie Park (AU)

(21) Appl. No.: 13/808,597

(22) PCT Filed: Jul. 6, 2011
(86) PCT No.: PCT/AU11/00855

§ 371 Date: May 22, 2013

(30) Foreign Application Priority Data
Jul. 7, 2010 (AU) 2010903014

(51) Int. Cl. H05K 7/00

(52) U.S. Cl. CPC H05K 7/00
USPC 361/679.01

(57) ABSTRACT

The Digital Addressable Lighting Interface (DALI) is a lighting control protocol that allows individual control and monitoring of each device in a lighting system (e.g. ballasts, emergency lighting etc), as well as groups of such devices. An improved DALI compliant Line Controller is described which may be advantageously used in a commercial setting. The sockets for both DALI lines and Ethernet are industry standard RJ45 sockets, allowing the use of industry standard cables (as compared to DB9 connectors which are not typically used in industrial settings). Further the use of RJ45 sockets enables the DALI controller to be SELV compliant, thus reducing the risk of electrical shock whilst working on the controller and advantageously providing a safer controller for use in an industrial environment. Additional modifications for use in an industrial environment include constructing DIN mountable slimline housing which extends along the DIN rail to minimise the footprint of the controller and increase packing efficiency on the rack, providing an externally accessible battery compartment on the top surface allowing quick and easy battery replacement without requiring removal of the controller from the DIN rack, and LED visual indicators on the top surface to provide status information and allow easy identification of a specific controller with a problem when mounted on a DIN rack with many other devices.

### PRIORITY DOCUMENTS

The present application claims priority from Australian Provisional Patent Application No. 2010903014 entitled “A DALI CONTROLLER” filed on 7 Jul. 2010; the entire content of which is hereby incorporated by reference.

### FIELD OF THE INVENTION

The present invention relates to lighting controllers. In a particular form the present invention relates to lighting controllers for use in a Digital Addressable Lighting Interface System (DALI).

### BACKGROUND OF THE INVENTION

The Digital Addressable Lighting Interface (DALI) is a lighting control protocol that allows individual control and monitoring of each device in a lighting system (e.g. ballasts, emergency lighting etc), as well as groups of such devices. DALI evolved from Digital Signal Interface (DSI) to become an open standard now defined in IEC 60929. The standard defines the communications protocol and electrical interface for compliant devices, and allows 64 DALI compliant devices to be supported on a single loop or network.

A DALI Communications Interface unit is used to communicate with devices on a DALI network (also referred to as a loop or line) and may be connected to a controller or gateway device to allow connection of the DALI network to a computer or other network. DALI controllers may include a clock and be used provide scheduling of DALI groups for scheduled occupancy, sequencing for override timers and effect lighting. The controller may also provide local intelligence enabling operation in the absence of a network connection.

DALI systems thus provide a great degree of flexibility and control of lighting systems, allowing control and monitoring of individual devices such as ballasts and emergency fittings, as well as groups of such devices. However the limitation of 64 devices limits use to small areas, and thus a single DALI network can not be provided for many commercial environments or buildings. To address this, DALI controllers/gateways have been produced which allow connection of a DALI network to a local area network (LAN), thereby allowing central control or integration into a building automation system Such connections have typically used a DB9 (RS232) type connector.

However DALI controllers have suffered from a number of limitations that limit efficient use in commercial environments. Firstly DALI is not a Safe Extra Low Voltage (SELV) compliant network and thus carries an increased risk of electric shock. Further as DALI controllers are connected via DB9 connectors (which are not SELV compliant), the DALI controllers are also not SELV compliant. Secondly commercial environments typically require power to be supplied to multiple zones in multiple areas (eg different floors or buildings), with each zone having different usage and lighting requirements, each of which will require one or more DALI controllers. In such settings many tens to hundreds of DALI controllers may be required. Typically the DALI controllers will be located in a single area such as a server room, or in only a few areas, such as in individual server rooms for each floor. Space and access is often limited in such areas and prior art DALI controllers have generally been non descript rectangular boxes and thus occupy considerable space on such racks. Further as they have generally used DB9 connectors, which are not typically found in commercial environments, an additional burden is placed on installers to carry suitable connectors. Further as they have been provided in non descript boxes, locating a controller with a problem or requiring maintenance can be a time consuming task.

There is thus a need for a DALI controller that is more suitable for use in a commercial environment than prior art controllers, or at least to provide a useful alternative to current controllers.

### SUMMARY OF THE INVENTION

According to a first aspect of the present invention, there is provided a DALI compliant line controller comprising:
at least one DALI line socket for connection to a DALI Communications Interface of a DALI network, wherein the DALI line socket protects the controller against electrical shocks arising from connection with the DALI network.

The line socket may be a RJ45 line socket. In use, the connection to the DALI Communications Interface may be via a connection cable comprising two RJ45 connectors on either end.

The DALI line controller may further comprise a communications network module for connecting the DALI controller to a computer network. The DALI compliant line controller may further comprise a plurality of externally viewable status indicators, comprising at least one communications network status indicator and at least one DALI status indicator. The at least one communications network status indicator may comprise a network link status indicator and a network activity status indicator located on a top surface of the DALI compliant line controller near one end of the DALI compliant line controller, and the at least one DALI status indicator may comprise a DALI activity status indicator and a DALI alert status indicator located on a top surface of the DALI compliant line controller near an opposite end of the DALI compliant line controller.

The communications network module may further comprise a RJ45 Ethernet socket for connection to an Ethernet network, and the RJ45 Ethernet socket may be located at the end of the controller with the network link status indicator and the network activity status indicator, and the at least one DALI line socket may be located at the opposite end of the controller with the DALI activity status indicator and an DALI alert status indicator.

The DALI compliant line controller may further comprise a plurality of digital inputs for control of DALI devices via the at least one DALI line socket and a plurality of digital outputs for controlling one or more devices based upon information received from one or more DALI devices via the at least one DALI line socket. The plurality of digital inputs may be located on one side of the DALI controller and the plurality of digital inputs may be located on the other side of the DALI controller.

The DALI compliant line controller may further comprise a battery compartment and an externally accessible battery cover to allow in-situ replacement of an internal battery located in the battery compartment. The battery cover may be located on an upper surface of the controller.

The DALI compliant line controller may further comprise a mounting arrangement located on the bottom of the controller for mounting the controller on a DIN rail, and the length of the DALI compliant line controller is at least twice the width of the DALI compliant line controller such that in use the DALI compliant line controller will extend along the DIN rail.

In a second aspect of the present invention there is provided a DALI compliant line controller for connection to a DALI network and a communications network, comprising:
a plurality of externally viewable status indicators, comprising at least one communications network status indicator and at least one DALI status indicator.

The at least one communications network status indicator may comprise a network link status indicator and a network activity status indicator located on a top surface of the DALI compliant line controller near one end of the DALI compliant line controller, and the at least one DALI status indicator includes a DALI activity status indicator and a DALI alert status indicator located on a top surface of the DALI compliant line controller near an opposite end of the DALI compliant line controller. The communications network module may further comprise a RJ45 Ethernet socket for connection to an Ethernet network, and the RJ45 Ethernet socket is located at the end of the controller with the network link status indicator and the network activity status indicator, and the at least one DALI line socket is located at the opposite end of the controller with the DALI activity status indicator and an DALI alert status indicator.

In a third aspect of the present invention there is provided a DALI compliant line controller comprising:
a battery compartment and an externally accessible battery cover to allow in-situ replacement of an internal battery located in the battery compartment.

The battery cover may be located on an upper surface of the controller.

In a fourth aspect of the present invention there is provided a DALI compliant comprising:
a mounting arrangement located on the bottom of the controller for mounting the controller on a DIN rail, and the length of the DALI compliant line controller is at least twice the width of the DALI compliant line controller such that in use the DALI compliant line controller will extend along the DIN rail.

In a fifth aspect of the present invention there is provided a DALI system comprising at least one DALI network comprising, a DALI communications interface and at least one DALI compliant line controller comprising at least one DALI line socket for connection to the DALI Communications Interface, wherein the DALI line socket protects the controller against electrical shocks arising from connection with the DALI network.

The DALI compliant line controller may further comprises a communications network module for connecting the DALI compliant line controller to a communications network.

### BRIEF DESCRIPTION OF THE DRAWINGS

An illustrative embodiment of the present invention will be discussed with reference to the accompanying drawings wherein:

FIG. 1 is front and rear perspective views of an embodiment of a DALI compliant line controller according to an embodiment of the present invention;

FIG. 2 is a top and side view of an embodiment of a DALI compliant line controller according to an embodiment of the present invention;

FIG. 3 is a power and interface wiring diagram for a DALI line controller according to an embodiment of the present invention;

FIG. 4 is diagram of power connection for daisy chaining two DALI line controllers according to an embodiment of the present invention;

FIG. 5 is an example of a wiring diagram for connection of input devices to a DALI line controller according to an embodiment of the present invention;

FIG. 6 is an example of a wiring diagram for connection to output devices from a DALI line controller according to an embodiment of the present invention;

FIG. 7 is schematic diagram illustrating a removable battery cover and battery compartment of a DALI line controller according to an embodiment of the present invention;

FIG. 8 is a schematic diagram of a DALI Line controller according to an embodiment of the present invention;

FIG. 9 is a schematic diagram of a DALI Line controller according to an embodiment of the present invention;

FIG. 10 is a schematic diagram of a DALI Line controller according to an embodiment of the present invention;

FIG. 11 is a schematic diagram of a DALI Line controller according to an embodiment of the present invention; and

FIG. 12 is a schematic diagram of a DALI Line controller according to an embodiment of the present invention.

In the following description, like reference characters designate like or corresponding parts throughout the several views of the drawings.

### DESCRIPTION OF ILLUSTRATIVE EMBODIMENTS

DALI systems provide a great degree of flexibility and control of lighting systems, allowing control and monitoring of individual devices such as ballasts and emergency fittings, as well as groups of up to 64 devices. In order to facilitate use in commercial environments a DALT controller has been developed and various illustrative embodiments will now be described. The DALI controller acts as an interface between an individual DALI network (the DALI devices themselves), input devices used to receive commands to the DALI network, output devices to allow control of other devices in coordination with devices in the DALI network, and to enable connection to a computer network (eg for remote command, control and monitoring). The controller can also be programmed to store schedules and to independently perform various control, monitoring and scheduling functions of the DALI network (i.e. stand alone mode). In this context a DALI compliant line controller is controller which is compliant with the DALI standard (IEC 60929), and thus able to monitor devices and communicate with DALI devices using DALI protocols over a DALI network.

DALI networks are not SELV compliant and as DALI controllers have typically been connected to the DALI network via a DALI Communications Interface device using a cable with a DB9 connector, the DALI controllers have also not been SELV compliant. A SELV circuit or device is one in which, under normal conditions or single fault conditions (including earth faults in other circuits) the electrical potential of any conductor against earth (ground) is not more than either 25 volts RMS (35 volts peak) for alternating current, or ripple-free 60 volts for direct current under dry conditions. SELV circuits are required to have protective separation from circuits that may carry higher voltages such as a DALI network (eg through the use of an insulation transformer and minimum separation of conductors and insulation barriers). Further electrical connectors for SELV devices should not allow mating with connectors used for non SELV circuits. A list of SELV compliant plugs and sockets has been published by the International Electrotechnical Commission (IEC) in standard: IEC 60906-3:1994.

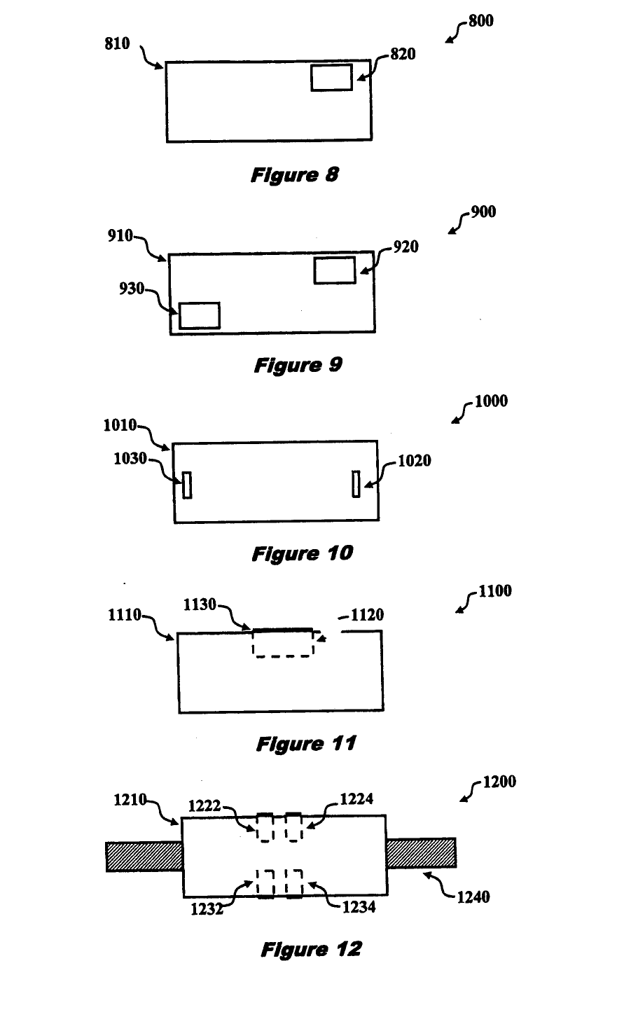

Prior art DALI controllers have typically been connected to a DALI isolated communications interface via a cable with a DB9 connector and thus have not been SELV compliant. To address this FIG. 8 is a schematic diagram 800 of a DALI compliant line controller 810 which includes a DALI line socket 820 for connection of the DALI line controller to the DALI isolated communications Interface (DALI gateway) wherein the DALI line socket 820 protects the controller against electrical shocks arising from connection with the DALI network. This enables the DALI compliant line controller to also be SELV compliant (that is the socket may be a SELV compliant socket). To enable communication with the DALI communications interface a socket and connector with at least 8 lines is required. The SELV compliant socket may be for receiving an RJ45 connector, 8P8C modular connector or other connectors. The use of an a RJ45 socket for receiving an RJ45 connector enables connection of the DALI controller and DALI Communications interface using a standard Cat 5 cable with RJ45 connectors at either end. Not only does this modification enable SELV certification of the DALI Controller (as it utilising a SELV compliant socket), and thus provide a safer line controller than has previously been available, but it also reduces the burden on installers as DB9 connectors are relatively uncommon in commercial settings compared to RJ45 connectors. Modification of the controller with RJ45 sockets thus eliminates the need for installers to carry around cables with DB9 connectors, or a RJ45 to DB9 connector, thereby simplifying installation and maintenance.

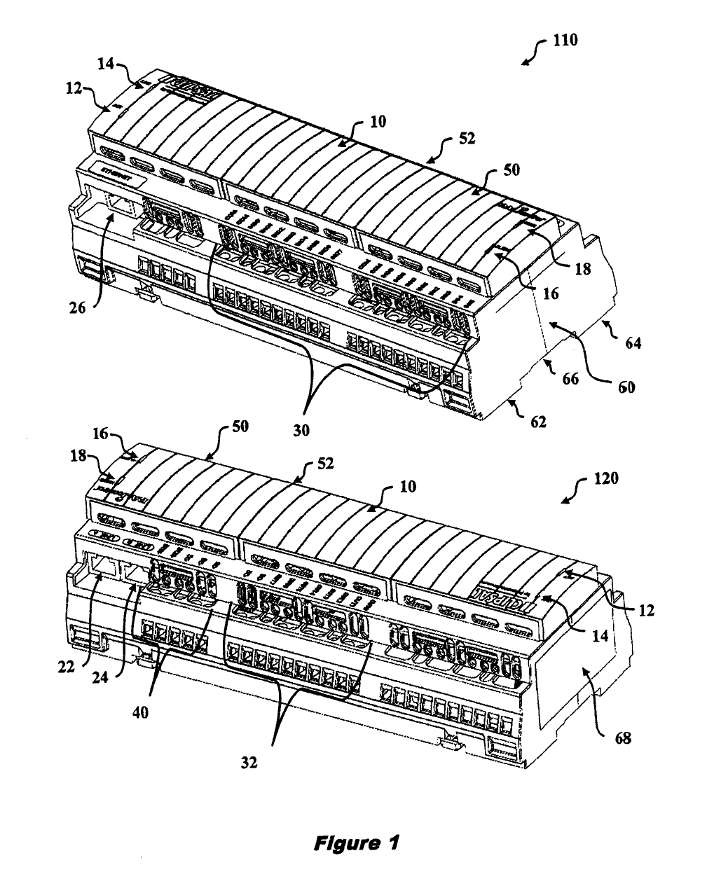

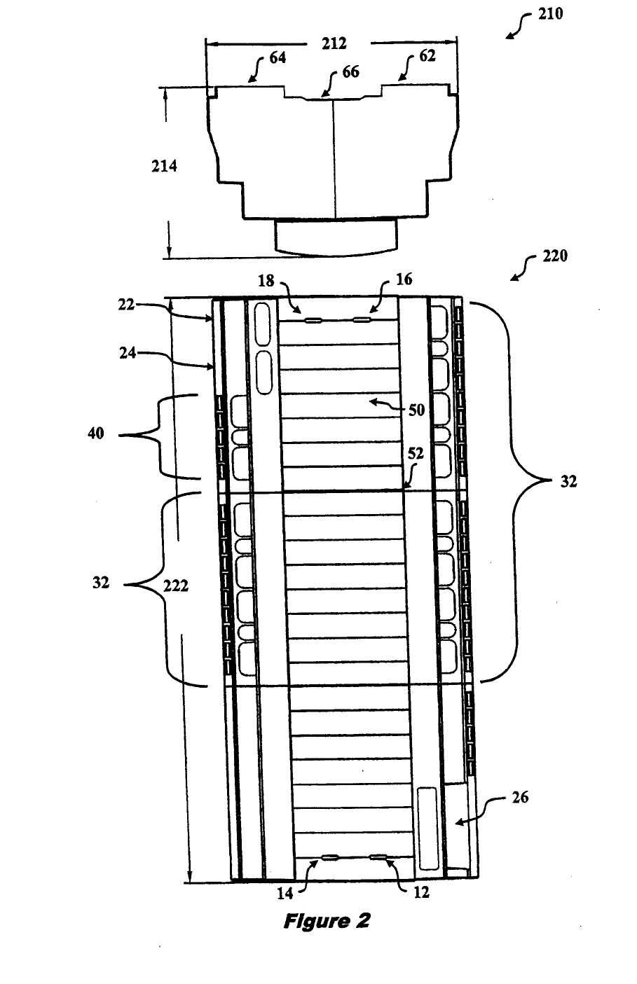

Referring now to FIG. 1, there is shown front 110 and rear 120 perspective views of an embodiment of a DALI compliant line controller according to an embodiment of the present invention (hereafter referred to as a DALI line controller, or more simply as a controller). FIG. 2 shows a top 220 and side 210 view of the DALI line controller shown in FIG. 1. The controller is capable of supporting one or two DALI networks or lines 22 24 as well as providing an Ethernet connection 26 to allow connection to a LAN, computer or other related devices. A plurality of digital inputs 30 are provided along one side of the body of the controller to receive inputs from control devices and plurality of digital outputs 32 are provided along the other side of the controller to send output commands to other devices. The top cover 10 also includes an externally accessible removable battery cover 50 (located on one end of the cover and joining the fixed cover at line 52) to allow easy in-situ replacement of a long life battery. External LED indicators 12 14 16 18 are also provided to allow status of the controller, and associated Ethernet and DALI network status to be visually observed. This is particularly useful when there are multiple controllers mounted on the same electronics rack.

Prior art line controllers have generally been provided in box like configurations which make inefficient use of space in commercial settings. Accordingly the line controller has been designed to allow mounting on a standard DIN rail with a slim and relatively compact footprint which does not extend significantly outward (transverse) from the DIN rail. DIN rails are standardized 35 mm wide metal rail with a top hat-shaped cross section which is widely used for mounting circuit breakers and industrial control equipment inside equipment racks. The controller shown in FIGS. 1 and 2 occupies 12M space on a standard DIN rail thereby allowing efficient mounting on commercial equipment racks. The controller can be mounted in the horizontal or vertical position (depending upon the orientation of the DIN rails). The DALI controller illustrated in FIGS. 1 and 2 may have a width 212 of 92 mm, a height 214 of 63 mm and a length 222 of 216 mm. The lower edge of side wall 60 includes two feet 62 and 64 and an inset portion 66 designed to match the profile of a standard DIN rail. The controller thus has a width just under three times the width of a standard DIN rail. In this embodiment the length is at least twice the width to give a slim such that when mounted the DALI compliant line controller will extend along the DIN rail and allow closer packing of DIN rails than with previous DALI line controllers. This allows a greater number of line controllers to be mounted in a confined space. A label portion 68 may be provided on one of the end plates. By designing the controller to be compatible with standard DIN rails, the controllers can be easily mounted along side other electrical equipment on standard racks found in commercial premises, and specialist mounting arrangements are not required, thereby simplifying the installation and removal of devices in a commercial environment.

When installing the controller enough space on each side of the Line Controller should be provide to allow for the number of cables to be installed. Additionally control or network wiring should not be next to power mains cabling as the AC cables could induce noise or interference and this could cause operational errors. In this embodiment the controller is SELV rated and thus appropriate wiring should be used. Ethernet connections may utilise Cat.5e Unshielded Twisted Pair (UTP) via an RJ45 socket or connector.

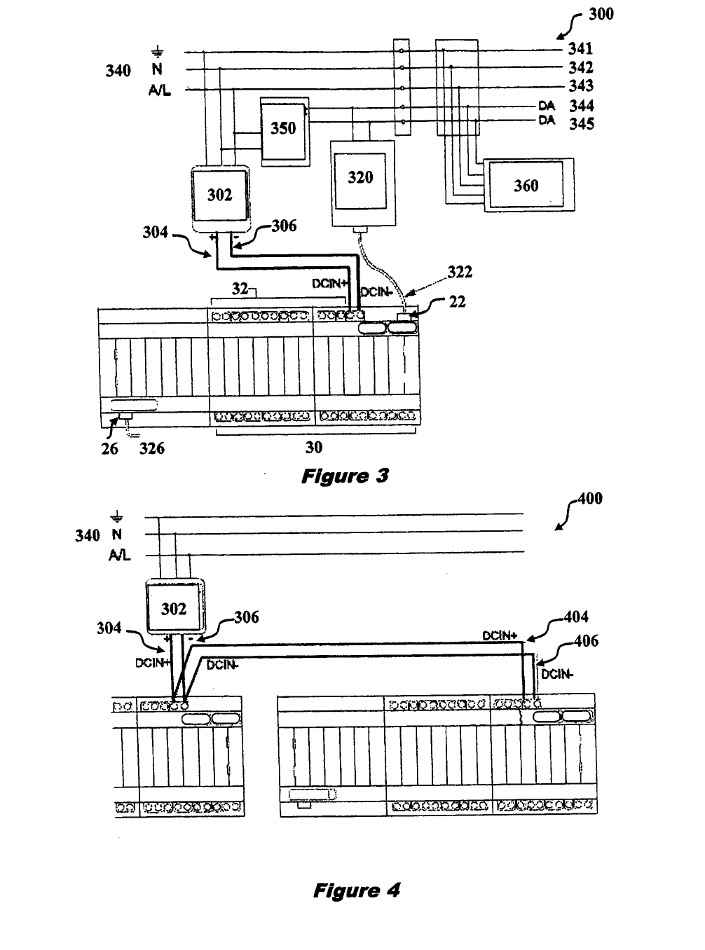

FIG. 3 is a power and interface wiring diagram 300 for a DALI line controller according to an embodiment of the present invention. Other wiring arrangements may be used. When power is applied, the controller performs a self test and activates the indicator LEDs. Each time the controller is unplugged and plugged into the power supply module the unit is reset and any configuration files may need to be reloaded. An internal lithium battery located in an externally accessible battery compartment 50 maintains the clock time when the controller is unplugged.

This embodiment of the controller can support one or two DALI communication lines. Each DALI line (Line A 22 or Line B 24) requires a DALI Communications Isolated Interface unit 320 and is connected by a DALI interface cable 322 (eg Cat 5e or RS485 patch cord) provided with RJ45 connectors on both ends. A suitable interface unit is the DCDALCI2 manufactured by Clipsal Australia. A current limited power supply 350 is required for each DALI line as shown in FIG. 3. A suitable power supply is the DCDALP manufactured by Clipsal Australia The DALI lighting system comprises 5 wires which are connected to each of the luminaries (ballasts) in the network and comprise an Active Line 343, Neutral line 342 and Earth 341 and 2 wires 344 345 for the DALI communications network. The Earth Neutral and Active Lines can be supplied from a circuit breaker 340. The luminaries are typically supplied with a flex cable and a 5-pin plug. An alternative wiring solution is the ‘Softwire’ system consisting of 5-pin T-pieces and interconnecting leads run within a ceiling or sub floor space. Cables are rated at 20 Amp and are terminated with 5-pin male and female ‘TAG’ connectors. The interconnecting leads are available in 500 mm increments. The luminaries are supplied with a flex cable and a 5-pin plug.

The DALI line controller may also be connected to a computer network such as a Local Area Network (LAN) or a Wide Area Network (WAN). This enables the DALI Line controller, and thus the DALI network (or networks) to be controlled or monitored from a remote location. A network communications module (including appropriate circuits and protocols) may be provided in the DALI line controller and may allow communication with a network via wired or wireless protocols. FIG. 9 is a schematic diagram 900 of a DALI line controller 910 including a SELV compliant socket 920 for connection to a DALI network via a DALI communications interface and a network communications module 930 for connection to a computer network.

To enable connection to a wired network, the line controller may be provided with a RJ-45 Ethernet socket 26 as illustrated in FIG. 1 A Cat 5e network cable 326 may be plugged into the RJ45 Ethernet socket to connect the controller to a broadband router. Alternatively the network communications module may include a wireless communications module to enable connection to a wireless router using an appropriate wireless connection protocol (eg IEEE 802.11, WiFi, Bluetooth, etc). In the case of an Ethernet connection protocol, each controller must be assigned a public IP address. An IP address may be assigned on a permanent or temporary basis. Typically up to 999 Line Controllers can be connected to the same wide area network (WAN) with each controller having a unique IP Address. Thus a large number of individual controllers can be connected to a computer network and centrally controlled and monitored.

The controller power supply module 302 requires a power outlet with an earth (ground) connection and should be connected to a building power circuit that is protected by a suitable circuit breaker or fuse 340 (not shown). The controller power supply unit 302 provides DCIN+ 304 and DCIN− 306 lines which are connected to the DCIN+ and DCIN− terminals on the topside of the controller. Multiple Line Controllers can be connected to a power supply via a daisy-chain layout 400 as illustrated in FIG. 4, wherein a first line 404 connects the DCIN+ terminals of two Line Controllers and a second line 406 connects the DCIN− terminals. In such cases the total electrical load of all connected devices that source current from the controllers should be added together to ensure the power supply is capable of supplying the required power. Care should be taken to ensure that polarity is correct for all power supply connections.

Input and output devices may be connected to the DALI Line controller via input and output connectors to receive input requests and to further control other devices in conjunction with DALI devices. For example an input device could be a switch indicating a presentation is to be held in a room. When a command is received from a switch to being the presentation, the lights in the room may be dimmed via the DALI network, and a command send to a motor controller to close the blinds in the room. To assist the installer when connecting input and output devices to the DALI controller, the location of the input connectors are separated from the location of the output connectors. FIG. 12 is a schematic top view 1200 of a DALI line controller 1210 mounted on DIN rail 1240. The two input connectors 1222 1224 are located along the upper side (above the DIN rail) and two output connectors 1232 1234 along the lower side (below the DIN rail). This arrangement enables the installer or maintainer to more quickly and easily locate the appropriate connector on the DALI device. This aspect is further illustrated in FIGS. 1-6, the input connectors are located along one side wall of the device, and all of the output connectors are located along the opposite side wall of the device.

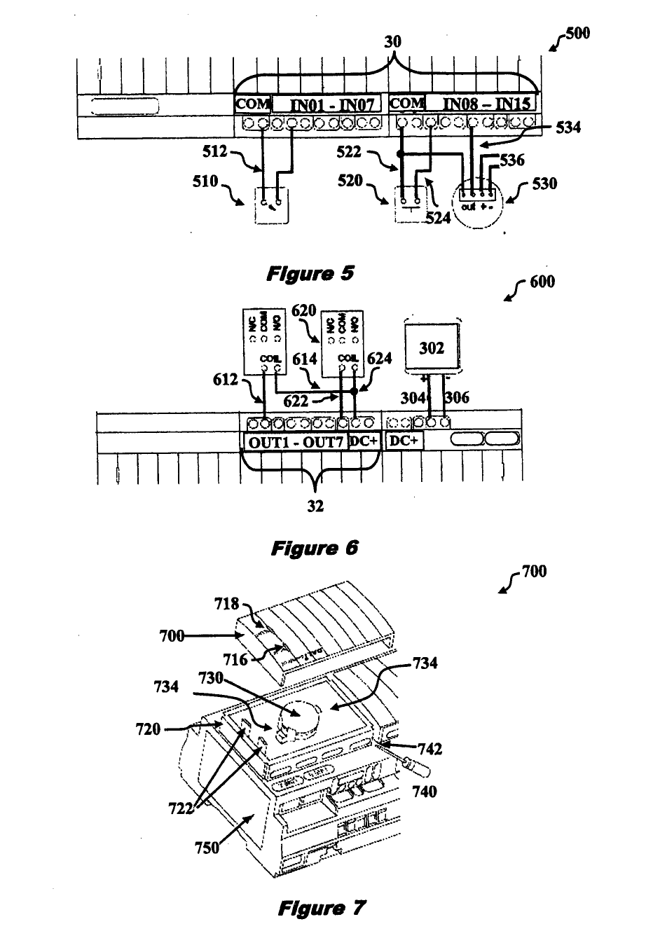

FIG. 5 is an example of a wiring diagram for connection of input devices to the input lines (terminals or connectors) 30 to the DALI line controller according to an embodiment of the present invention. The line controller has 16 protected digital inputs (IN0-IN15) 330 which are noise protected and can handle voltages from −36 V to +36 V. Input devices are usually switches or electronic control devices. In FIG. 5 the input devices comprise a switch 510, a pushbutton 520 and a light sensor 530 which are connected to inputs IN01, IN08 and IN11 of the DALI line controller. The light sensor 530 is further connected to a power supply (not shown).

FIG. 6 is an example of a wiring diagram for connection of output devices to output lines (terminals or connectors) 32 from the DALI line controller according to an embodiment of the present invention. The line controller has 8 digital outputs (OU0-OU7), each of which can sink up to 200 mA (provided a power supply is selected that that provides enough power for all of the connected devices). The output devices illustrated in FIG. 6 comprise a first relay 610 which is connected to output line OU01 and a second relay 620 which is connected to output line OU07. The first and second relays are both connected to the DC+ supply 632 of the line controller, which is supplied power via controller power supply 630 which is connected to the DCIN+ and DCIN− terminals of the line controller.

The DALI line controller may also be provided with a plurality of visual status indicators on an external surface to allow an installer to rapidly determine if a line controller is functioning as expected, or to allow easy identification of a line controller with a problem. FIG. 10 is a schematic view 1000 of a DALI line controller 1010 according to an embodiment of the invention. The DALI Line controller 1000 has a first indicator 1020 located near one end of the controller and a second indicator 1030 located near the other end of the controller. However they need not be located on opposite sides and could be located next to each other, and may be located on the top surface, or a side or end surface. If there are several indicators then these may be grouped together on the basis of type (activity or alert) and or associated functional component (DALI network, internal circuits, Ethernet or communications network). For example the indicators may indicate presence of an Ethernet link, Activity on the Ethernet Link, DALI Activity, and a DALI Alert with the Ethernet indicators grouped and located in one location, and the DALI indicators grouped and located in a separate location.

In the embodiment shown in FIGS. 1 to 7, four visual status indicators 12, 14, 16, 18 are located on the top surface. The four indicators comprise four LEDs which are located on an internal circuit board, and associated light pipes which direct light from the respective LEDS to the surface of the controller. The cover of the controller is provided with openings for receiving the light pipes. This is shown more clearly in FIG. 7 which illustrates removal of the battery cover 710. Battery cover 710 includes openings (apertures) 716 and 718 for receiving light pipes 726 and 728 which supply light from LED indicators located in the internal electronics of the line controller. Placing visual status indicators on the top surface 10 of the controller allows a technician to rapidly determine if a line controller is functioning as expected, or to allow easy identification of a line controller with a problem. This is particularly useful when multiple controllers are co-located on the same rack or on multiple racks in a common area as the technician can easily determine which network or controller has a problem and requires attention. Further to assist in visual recognition of status or problems, indicators relating to the Ethernet link are provided at the end of the controller adjacent to the Ethernet connector 26, and indicators relating to the DALI network are provided on the other end of the controller adjacent to the DALI network connectors 22 24.

An Ethernet Link Status LED 14 is provided which is continuous green when there is an active connection to the Ethernet LAN. An Ethernet Activity Status LED 12 is provided which flashes when Data is being transmitted between the Line Controller and the rest of the network.

A DALI Activity (or mode) Status LED 18 is also provided. When the controller is first turned on the Activity Status LED will be solid green to indicate that the board has power. After five seconds the Line Controller will indicate that it has finished its internal initializing by cycling the green Activity Status LED. The indicator will change state every three seconds when in Run mode. When the Line Controller is in Stop mode the indicator will flash red with a 500 mS period. A DALI Alert Status LED 16 is also provided. This is continuously red when one of the DALI devices being polled for status has reported an error condition which may be:
Comms error—the controller cannot communicate with the DALI device with the configured short address;
Ballast error—the DALI device is reporting a ballast error; or
Lamp failure—the DALI device is reporting a lamp failure;

These thus provide a visual indication of the status of the controller and associated Ethernet and DALI networks. Thus in a commercial environment with many controllers installed on the same rack, and multiple racks located in a confined space, a technician can easily identify whether all devices are working, or easily locate a device with a problem, as well as ascertain where the fault exists (Ethernet connection or DALI network) based upon which side of the controller the indicators are located.

The Line Controller has an inbuilt real-time clock. The clock maintains the current time and date when the power supply unit is unplugged. A non-rechargeable battery is installed at the factory. The battery is designed to last for up to 10 years. However, prolonged periods when the unit is unplugged will shorten battery life. The real-time clock aids in scheduling the inputs for switches and sensors and also the advanced communications capabilities for integrating access control, security panels and computer networks. A suitable battery backup is a 3V lithium coin battery (CR2477N).

In previous line controllers, the battery has been located on an internal circuit board. Thus when the battery is required to be replaced, the line controller case must be opened up to gain access to the internal circuits and the battery. This typically requires disconnection of all inputs, outputs, and power supplies, as well as removal of the device from the rack or mounted position to provide sufficient access to casing and parts, or to prevent a potential loss of parts once the casing is opened up. This adds considerable time and effort to the operation. In a commercial setting, it is typical (for efficient maintenance) to replace all the batteries in all line controllers at the same time, these operations may add up to a significant amount of time. Accordingly to facilitate ease of access to the battery and speed up battery changing operations, an externally accessible battery compartment with a removable cover is supplied to enable in-situ changing of the battery. FIG. 11 is a schematic diagram 1100 of a DALI controller 1110 comprising a battery compartment 1120 with an externally accessible removable cover 1130.

An embodiment of a battery compartment and cover is further illustrated in FIG. 7, which is an isometric view 700 of a DALI line controller with the battery cover 710 removed and illustrating the battery compartment 720. Inclusion of a removable battery covers provides easy access and allows replacement of an internal battery 730. In this embodiment the battery cover 710 is located on the top surface to ensure ease of access and enables in-situ replacement of the battery without having to disassemble the controller, or remove the controller from the DIN mounting, thus saving considerable time. As is illustrated in FIGS. 1 and 2, the battery cover 50 meets the fixed over 10 at join line 52 and has been designed to visually resemble the rest of the cover 10. The battery cover 710 is designed to clip over the battery compartment 720 and is manufactured from suitable plastic having sufficient resiliency to enable clipping and unclipping of the battery cover. In the embodiment shown in FIG. 7, the cover has two side walls which are designed to grip the sidewalls of the battery compartment. The battery may be replaced by first disconnecting the power supply from the controller for safety.

The cover may be released by first prying the end of the removable cover 710 upward using a small screwdriver 740 inserted at one end of the battery cover such as location 742. This temporarily deforms the edge of the cover and thus releases the covers grip on the compartment. The top cover may then be removed from the unit and set aside. The indicator lenses or light pipes 722 may separate from the interior circuit board located below the battery compartment 720 in which case they should be set aside with the cover whilst replacing the battery. The old battery 730 may be removed by simply pulling the battery upward using the installers fingers—no tools are required (the battery should then be disposed off properly). A new battery (eg Renatta CR2477N) may then be removed from packaging and placed into the plastic clips 732 734. The battery should then be pressed into position so that it is held firmly by the clips 732 734. Finally the indicator lenses 722 should be inserted (if required) and checked to ensure they are properly seated and then the top cover 710 should be pressed downward over the battery compartment 720 and checked to ensure the cover is firmly in place. The power supply should be reconnected, and as power has been lost to the controller configuration files may need to be reloaded when power is restored. The date that the battery is changed can be updated on a label 750 affixed to the side of the controller.

A battery compartment could be provided elsewhere on the exterior surface provided it is still accessible when mounted and does not require disassembly of the controller or access to other internal components. Access to the battery compartment could also provided using cover in the form of a panel which is screwed or fastened to the battery compartment. The panel may further include one or more projections designed to be inserted into matching recesses in the battery compartment or cover.

The DALI Line Controllers may be designed (eg provided with suitable circuitry and/or control modules) to enable independent operation so that the controller can continue to process local inputs and schedules when disconnected from the network, and thus need not be reliant on a server. The controller may also be used to provide scheduling of DALI groups for scheduled occupancy, sequencing for override timers and effect lighting. The controller may also provide local intelligence and may include one or more of the following features:

a) Integrated real time clock with automatic daylight savings adjustment and leap-year correction.

b) Integrated sunrise/sunset support based on site location (latitude and longitude).

c) 100 Time Schedules to control groups for scheduled occupancy with support for holiday exceptions.

d) 20 Holidays for exception schedules.

e) 16 multi-function digital inputs for operator pushbuttons and sensors including occupancy sensors and daylight sensors.

f) 8 digital outputs for additional control and interlocking to external equipment such as fans, valves and security panels each capable of sinking 200 mA.

g) 32 configurable sequences for override sequences, mood and effect lighting.

h) Support of one or two DALI lines (up to DALI 128 ballasts).

i) An in-built web server for error reporting of DALI loop, ballast and lamp failures.

j) Local processing. In the event of network failure or disconnection from the Ethernet network the controller is to continue to run automatic time schedules and process inputs independently using the integrated real time clock.

k) Computer monitoring and configuration. The controller may allow configuration, monitoring and analysis from computers on the Ethernet network.

l) Computer control. The controller may allow occupants to control their local lighting using their computers on the network.

Such functionality may be provided by one or more circuits, including one or more microprocessors (and associated memory) located within the housing of the DALI controller.

The DALI Line Controller may provide manual control, scheduled occupancy control, automatic occupancy control and daylight harvesting to dim down the electric lighting in response to daylight admittance. Further the DALI Line Controller can be configured to utilize timed schedules, occupancy sensors, light sensors and switches to control the lighting in the interior spaces on each floor. In this way electric light can be provided only when the space is occupied and at the minimum level required light level for the work plane.

In a commercial setting, the limitation of 64 devices on an individual DALI network limits scalability. Thus DALI controllers can be manufactured to support multiple such DALI networks, and through provision of an Ethernet connection can be connected to sites computer network, and/or to a building automation or maintenance system. In this way individual controllers can control the lighting on a particular floor or particular regions of a building, such as for board rooms, meeting rooms or office space.

Embodiments of the DALI compliant Line Controller described herein may be advantageously used in a commercial setting. The sockets for both DALI lines and Ethernet are industry standard RJ45 sockets, allowing the use of industry standard cables (as compared to DB9 connectors which are not typically used in industrial settings). Further the use of RJ45 sockets enables the DALI controller to be SELV compliant, thus reducing the risk of electrical shock whilst working on the controller and advantageously providing a safer controller for use in an industrial environment. Additional modifications for use in an industrial environment include constructing DIN mountable slimline housing which extends along the DIN rail to minimise the footprint of the controller and increase packing efficiency on the rack, providing an externally accessible battery compartment on the top surface allowing quick and easy battery replacement without requiring removal of the controller from the DIN rack, and LED visual indicators on the top surface to provide status information and allow easy identification of a specific controller with a problem when mounted on a DIN rack with many other devices.

Those of skill in the art would understand that information and signals may be represented using any of a variety of technologies and techniques. For example, data, instructions, commands, information, signals, bits, symbols, and chips may be referenced throughout the above description may be represented by voltages, currents, electromagnetic waves, magnetic fields or particles, optical fields or particles, or any combination thereof.

Throughout the specification and the claims that follow, unless the context requires otherwise, the words “comprise” and “include” and variations such as “comprising” and “including” will be understood to imply the inclusion of a stated integer or group of integers, but not the exclusion of any other integer or group of integers.

The reference to any prior art in this specification is not, and should not be taken as, an acknowledgement of any form of suggestion that such prior art forms part of the common general knowledge of the person skilled in the art, or is widely known in the art.

It will be appreciated by those skilled in the art that the invention is not restricted in its use to the particular application described. Neither is the present invention restricted in its preferred embodiment with regard to the particular elements and/or features described or depicted herein. It will be appreciated that the invention is not limited to the embodiment or embodiments disclosed, but is capable of numerous rearrangements, modifications and substitutions without departing from the scope of the invention as set forth and defined by the following claims.

1. A DALI compliant line controller comprising:
at least one DALI line socket for connection to a DALI Communications Interface of a DALI network, wherein the DALI line socket protects the controller against electrical shocks arising from connection with the DALI network.

2. The DALI compliant line controller as claimed in claim 1, wherein the at least one DALI line socket is a RJ 45 line socket.

3. The DALI compliant line controller as claimed in claim 1, further comprising a communications network module for connecting the DALI controller to a computer network.

4. The DALI compliant line controller as claimed in claim 3, further comprising:
a plurality of externally viewable status indicators, comprising at least one communications network status indicator and at least one DALI status indicator.

5. The DALI compliant line controller as claimed in claim 4, wherein the at least one communications network status indicator comprises a network link status indicator and a network activity status indicator located on a top surface of the DALI compliant line controller near one end of the DALI compliant line controller, and the at least one DALI status indicator comprises a DALI activity status indicator and a DALI alert status indicator located on a top surface of the DALI compliant line controller near an opposite end of the DALI compliant line controller.

6. The DALI compliant line controller as claimed in claim 5, wherein the communications network module further comprises a RJ45 Ethernet socket for connection to an Ethernet network, and the RJ45 Ethernet socket is located at the end of the controller with the network link status indicator and the network activity status indicator, and the at least one DALI line socket is located at the opposite end of the controller with the DALI activity status indicator and an DALI alert status indicator.

7. The DALI compliant line controller as claimed in claim 1, further comprising:
a plurality of digital inputs for control of DALI devices via the at least one DALI line socket; and
a plurality of digital outputs for controlling one or more devices based upon information received from one or more DALI devices via the at least one DALI line socket.

8. The DALI compliant line controller as claimed in claim 7, wherein the plurality of digital inputs are located on one side of the DALI controller and the plurality of digital inputs are located on the other side of the DALI controller.

9. The DALI compliant line controller as claimed in claim 1, further comprising:
a battery compartment and an externally accessible battery cover to allow in-situ replacement of an internal battery located in the battery compartment.

10. The DALI compliant line controller as claimed in claim 9, wherein the battery cover is located on an upper surface of the controller.

11. The DALI compliant line controller as claimed in claim 1, further comprising:
a mounting arrangement located on the bottom of the controller for mounting the controller on a DIN rail, and the length of the DALI compliant line controller is at least twice the width of the DALI compliant line controller such that in use the DALI compliant line controller will extend along the DIN rail.

12. A DALI compliant line controller for connection to a DALI network and a communications network, comprising:
a plurality of externally viewable status indicators, comprising at least one communications network status indicator and at least one DALI status indicator.

13. The DALI compliant line controller as claimed in claim 12, wherein the at least one communications network status indicator comprises a network link status indicator and a network activity status indicator located on a top surface of the DALI compliant line controller near one end of the DALI compliant line controller, and the at least one DALI status indicator comprises a DALI activity status indicator and a DALI alert status indicator located on a top surface of the DALI compliant line controller near an opposite end of the DALI compliant line controller.

14. The DALI compliant line controller as claimed in claim 13, wherein the communications network module further comprises a RJ45 Ethernet socket for connection to an Ethernet network, and the RJ45 Ethernet socket is located at the end of the controller with the network link status indicator and the network activity status indicator, and the at least one DALI line socket is located at the opposite end of the controller with the DALI activity status indicator and an DALI alert status indicator.

15. (canceled)

16. (canceled)

17. (canceled)

18. A DALI system comprising at least one DALI network comprising, a DALI communications interface and at least one DALI compliant line controller comprising at least one DALI line socket for connection to the DALI Communications Interface, wherein the DALI line socket protects the controller against electrical shocks arising from connection with the DALI network.

19. The DALI system as claimed in claim 18, wherein the DALI compliant line controller further comprises a communications network module for connecting the DALI compliant line controller to a communications network.
